(19) United States
(12) Patent Application Publication
(10) Pub. No.: US 2013/0069642 A1
(43) Pub. Date: Mar. 21, 2013

(54) Magnetic Sensor With Conducting Bevel

(71) Applicants: Victor Boris Sapozhnikov, Minnetonka, MN (US); Dimitar Velikov Dimitrov, Edina, MN (US)

(72) Inventors: Victor Boris Sapozhnikov, Minnetonka, MN (US); Dimitar Velikov Dimitrov, Edina, MN (US)

(73) Assignee: SEAGATE TECHNOLOGY LLC, Cupertino, CA (US)

(21) Appl. No.: 13/239,056

(22) Filed: Sep. 21, 2011

(51) Int. Cl. G01R 33/00; B05D 1/36

(52) U.S. Cl. 324/260; 427/470

(57) ABSTRACT

Various embodiments can have a magnetically responsive stack positioned on an air bearing surface (ABS) and disposed between at least first and second magnetic shields. Each magnetic shield may have a beveled portion distal to the ABS. The magnetically responsive stack can have a cross-track magnetization anisotropy proximal to the ABS.

### SUMMARY

A magnetic sensor can be constructed with a magnetically responsive stack positioned on an air bearing surface (ABS) and disposed between at least first and second magnetic shields. Each magnetic shield may have a beveled portion distal to the ABS. The magnetically responsive stack can have a cross-track magnetization anisotropy proximal to the ABS.

### BRIEF DESCRIPTION OF THE DRAWINGS

FIG. 1 is a perspective view of an example data storage device.

FIG. 2 shows a magnetic sensor as constructed and operated in accordance with various embodiments of the present invention.

FIG. 3 shows a magnetic sensor constructed and operated in accordance with various embodiments of the present invention.

FIG. 4 generally illustrates a magnetic shield capable of deflecting unwanted flux in various embodiments.

FIG. 5 provides a magnetic sensor capable of being used in the data storage device of FIG. 1.

FIGS. 6A and 6B show structural characteristics of a material capable of being used as the magnetic shield in the various embodiments of FIG. 2.

FIGS. 7A-7D display example magnetic sensor configurations in accordance with various embodiments of the present invention.

FIG. 8 provides a flowchart of an magnetic sensor fabrication routine carried out in accordance with various embodiments of the present invention.

### DETAILED DESCRIPTION

The present disclosure generally relates to enhancing performance of magnetic sensors, particularly by reducing noise and increasing input signals. Elevated data capacity and faster data transfer rates are continual goals of the data storage industry. With higher data capacity, form factors of various data storage components, such as read elements and shields, decrease, which consequently reduces the amount of space read elements can utilize. Such minimization of the size of magnetic shields and the usable space between those shields can lead to inaccurate data reading and higher error occurrences.

With trilayer read elements that have dual magnetic free layer with no pinned magnetization, smaller space between shields can correspond to less effective biasing magnets. A reduction in biasing magnet strength can result in greater magnetic instability for the read element as well as degraded data sensing. Various reduced form factor shield designs can accommodate a biasing magnet by beveling portions of the magnetic shields distal to the air bearing surface (ABS), but such beveling may reduce output signal amplitude due to the insufficient constriction of current along ABS portions of the read element

Accordingly, a magnetic sensor may be formed with a magnetically responsive stack positioned on an ABS and disposed between first and second magnetic shields that each has a beveled portion distal to the ABS. The stack can be constructed with cross-track anisotropy proximal to the ABS, which enhances the magnetically responsive areas of the sensor along the back edge of the sensor.

In various embodiments, the cross-track anisotropy can be combined with filling each beveled portion with a non-magnetic electrically conductive insert. Such an insert can extend along the area of signal generation in the stack while increasing magnetization stabilization without elevating stack resistance. The cross-track anisotropy can further enhance operational characteristics of the data read element by improving readback performance through reduction of reader noise and increased sensor area that is responsive to magnetic fields from media transitions, which can produce a larger sensed magnetic field and signal amplitude.

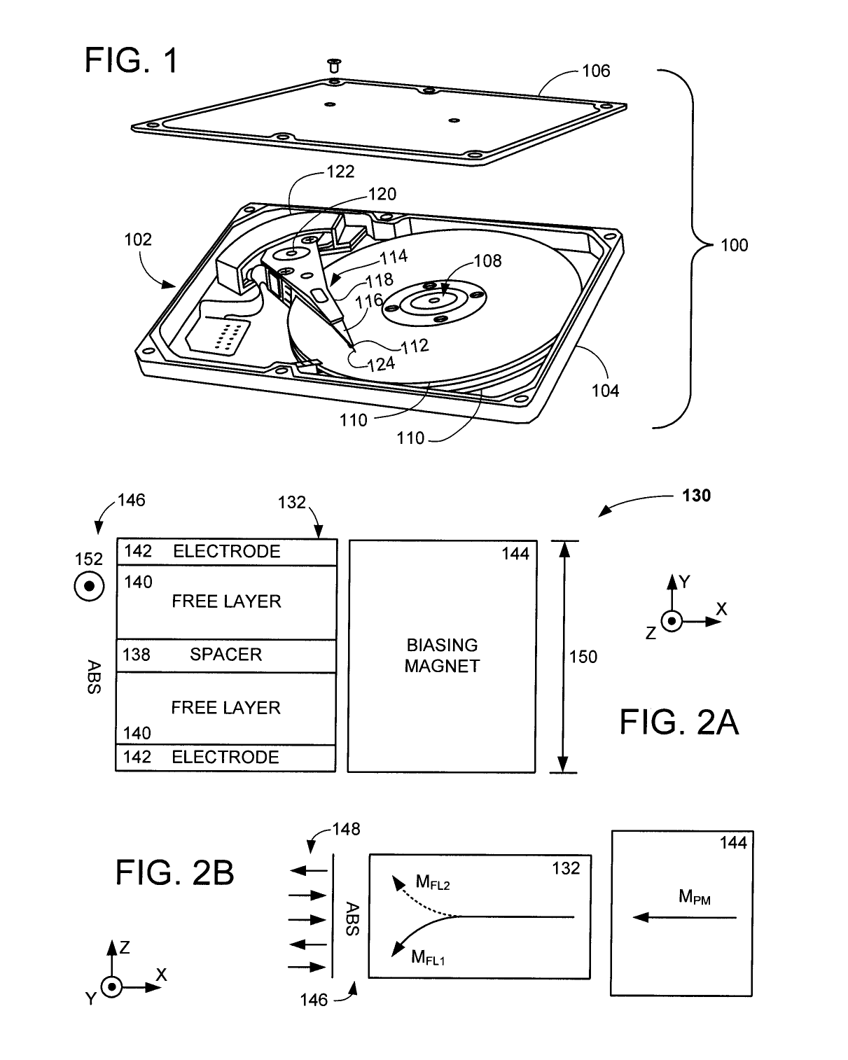

In FIG. 1, an embodiment of a data storage device 100 is shown in a non-limiting environment in which various embodiments of the present invention can be practiced. The device 100 includes a substantially sealed housing 102 formed from a base deck 104 and top cover 106. An internally disposed spindle motor 108 is configured to rotate a number of magnetic storage media 110. The media 110 are accessed by a corresponding array of data transducers (read/write heads) that are each supported by a head gimbal assembly (HGA) 112.

Each HGA 112 can be supported by a head-stack assembly 114 (“actuator”) that includes a flexible suspension 116, which in turn is supported by a rigid actuator arm 118. The actuator 114 may pivot about a cartridge bearing assembly 120 through application of current to a voice coil motor (VCM) 122. In this way, controlled operation of the VCM 122 can cause the transducers (numerically denoted at 124) to align with tracks (not shown) defined on the media surfaces to store data thereto or retrieve data therefrom.

FIGS. 2A and 2B generally illustrate side and top views of portions of an example magnetic sensor 130 capable of being used in the data storage device of FIG. 1. Construction of the magnetic sensor 130 is unlimited and can be a lamination of any number of layers with any magnetic orientation that is magnetically responsive. One such construction has a non-magnetic spacer layer 138 disposed between dual magnetically free layers 140 that are respectively attached to electrodes 142, which can be a variety of different orientations and materials, such as cap and seed layers.

With the presence of magnetically free layers 140 without a fixed magnetization in the magnetic stack 132 to be used as a reference, the stack 132 can be characterized as a trilayer reader element where a permanent magnet 144 is positioned adjacent the stack 132 opposite an air bearing surface (ABS) 146. The biasing magnet 144 can be configured to possess a remnant magnetization (M_{PM}) such that to create a bias field (H_bias) on the free layers 140 that sets the stack 132 to default magnetizations (M_{FL1} and M_{FL2}) that allows accurate sensing of data bits 148 across the ABS 146, as illustrated by FIG. 2B.

The magnetic sensor 130 can operate to sense data bits 148 passing within the shield-to-shield spacing (SSS) 150 of the sensor 130 and within a predetermined track width 152 by registering alteration in the default magnetizations. However, unwanted noise and weak readback signal amplitude can plague dual free layer 140 sensors 130, especially in reduced form factor applications, as merely a small fraction of the sensor 130 close to the ABS 146 can be responsive to the media field and contribute to the read-back signal.

The magnetic stack may be positioned between magnetic shields that block distal data bits generated from outside of the track while stabilizing the biasing magnet's 144 influence on the stack 132. Reduced form factors may be accommodated with beveled regions in at least one magnetic shield distal to the ABS 146 that increase SSS 150 and allow for stronger fields from the biasing magnet 144 while not increasing the overall shield-to-shield spacing of the sensor 130 at the ABS.

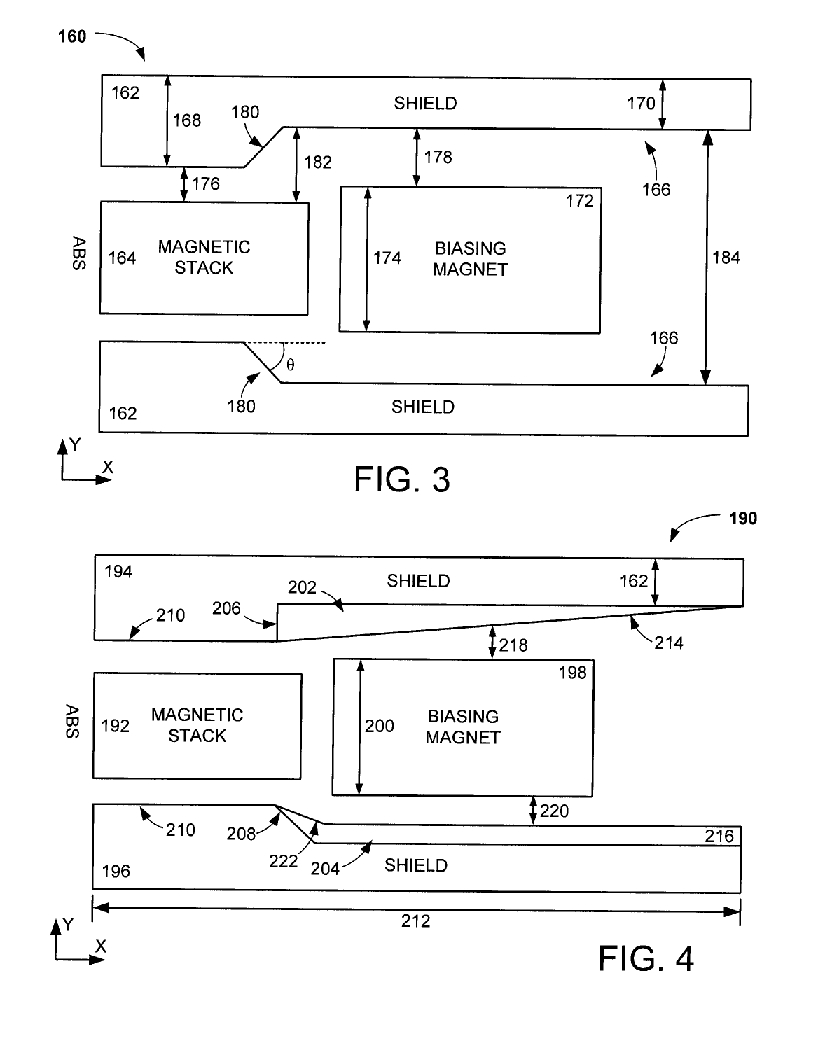

FIG. 3 provides a block representation of an example magnetic sensor 160 with such magnetic shields 162 positioned adjacent a magnetic stack 164. Each magnetic shield is configured with a beveled portion 166 that reduces the shield's thickness, along the Y axis, from an ABS thickness 168 to a bias thickness 170 distal the ABS. The beveled portions 166 each may reduce decay of magnetic field from the rear biasing magnet 172 while allowing for a biasing magnet thickness 174 that is greater than the thickness of the magnetic stack 164. The beveled portions 166 can further provide a predetermined stack-shield thickness 176 and magnet-shield thickness 178 that respectively tunes biasing fields in the stack 164.

The beveled portions 166 can collectively or independently be configured with transition regions 180 that translate the shield 162 from the ABS thickness 168 to the distal thickness 170. The transition region 180 is not limited to the tapered shape or position that provides a second stack-shield thickness 182 as shown in FIG. 3 and can be modified, at will, to any number of configurations, such as curvilinear, parallel to the ABS, and at a predetermined angle θ with respect to the X axis.

Operation of the magnetic shields 162 allows the stack 164 to sense only the magnetic fields within the SSS 184 at the ABS, which is particularly pertinent with reduce form factor data storage devices. The extra SSS 184 associated with the distal thickness 170 of the shields 162 can be filled, in some embodiments, with an insulating material that increases readback signal amplitude by constricting current in the magnetic stack 164 to an area proximal the ABS. However, such constriction of current in the stack 164 may also increase the electrical resistance, which can increase magnetic noise and reduce input signal from a preamplifier, which can minimizes readback signal amplitude gained by current constriction.

With current constriction potentially endangering performance of the magnetic stack 164, the area of data signal generation in the magnetic stack 164 can be extended by creating substantially cross-track magnetization anisotropy aligned along the Z axis. Furthermore, the insulating material filling the beveled portions 166 can be replace with an electrically conductive, but non-magnetic insert that may enhance stack 164 performance through increased magnetic stability, reduced electrical resistivity, and decreased stack 164 noise.

FIG. 4 generally illustrates a block representation of an example magnetic sensor 190 capable of being constructed and operated in various embodiments. The sensor 190 has a magnetic stack 192, such as a trilayer read element, disposed between top and bottom magnetic shields 194 and 196 on the ABS. The magnetic stack 192 is further disposed between the ABS and a biasing magnet 198 that has a thickness 200 along the Y axis, parallel to the ABS, that is accommodated by top and bottom beveled portions 202 and 204 that have independently shaped transition surfaces 206 and 208 that reduce the thickness of each shield 194 and 196 from a level portion 210 at a predetermined position along the sensor's stripe height 212.

Top and bottom bevel inserts 214 and 216 are respectively housed at least partially within the top and bottom beveled portions 202 and 204. The top bevel insert 214, as shown, is configured with a continuously varying thickness that extends throughout the top bevel portion 202 and corresponds with a varying distance 218 from the biasing magnet 198. The bottom bevel insert 216 has a substantially uniform thickness that corresponds with a uniform distance 220 from the insert 216 to the biasing magnet 198.

While not required or limited, the top and bottom bevel inserts 214 and 216 display some of the various transition surface and bevel insert shapes that can be utilized to tune and optimize the performance of the sensor 190. The multitude of structural configurations possible with the beveled portions and transition surfaces may compliment the variety of electrically conductive, but non-magnetic materials that can be utilized for the magnetic shields and bevel inserts to enhance magnetic stability in the stack 192 while reducing noise.

In some embodiments, one or more bevel inserts 214 and 216 are formed as a single layer of metallic material, such as Chromium, that conducts electricity, but not magnetization. Other embodiments form the bevel inserts 214 and 216 as a lamination of layers comprising one or more non-magnetic materials, such as Ruthenium and Tantalum. Regardless of the number of layers and the material composition of those layers, the electric conductivity and magnetic characteristics of the materials may provide enhanced magnetic stability in the stack 192 while allowing the biasing magnet 198 to efficiently operate without magnetic interference from the magnetic shields 194 and 196.

The position of the transition surface 206 along the sensor stripe height 212 can further allow for tuning and optimization of the stack 192 performance. Adjustment of the shape and location of the transition surface 206 may modify current constriction in the stack 192 and the amount of biasing field influencing the stack 192 from the biasing magnet 198. With the unlimited variety of transition surface 206 configurations, the bevel inserts 214 and 216 can likewise have portions that conform to the surface while having dissimilar shapes and thicknesses from other portions of the insert, such as insert portion 222 that can allow for gradual structural and operational conversions from the level portion 210.

The inclusion of bevel inserts 214 and 216 that are optimized for designed magnetic stack 192 operations provides increases magnetic stabilization and reduced noise, but can have limited influence on the size of data input signals. Construction of at least some of the magnetic stack 192 with substantially cross-track magnetization anisotropy can provide increased data signal generation that can be enhanced by the stable stack 192 magnetization provided by the bevel inserts 214 and 216.

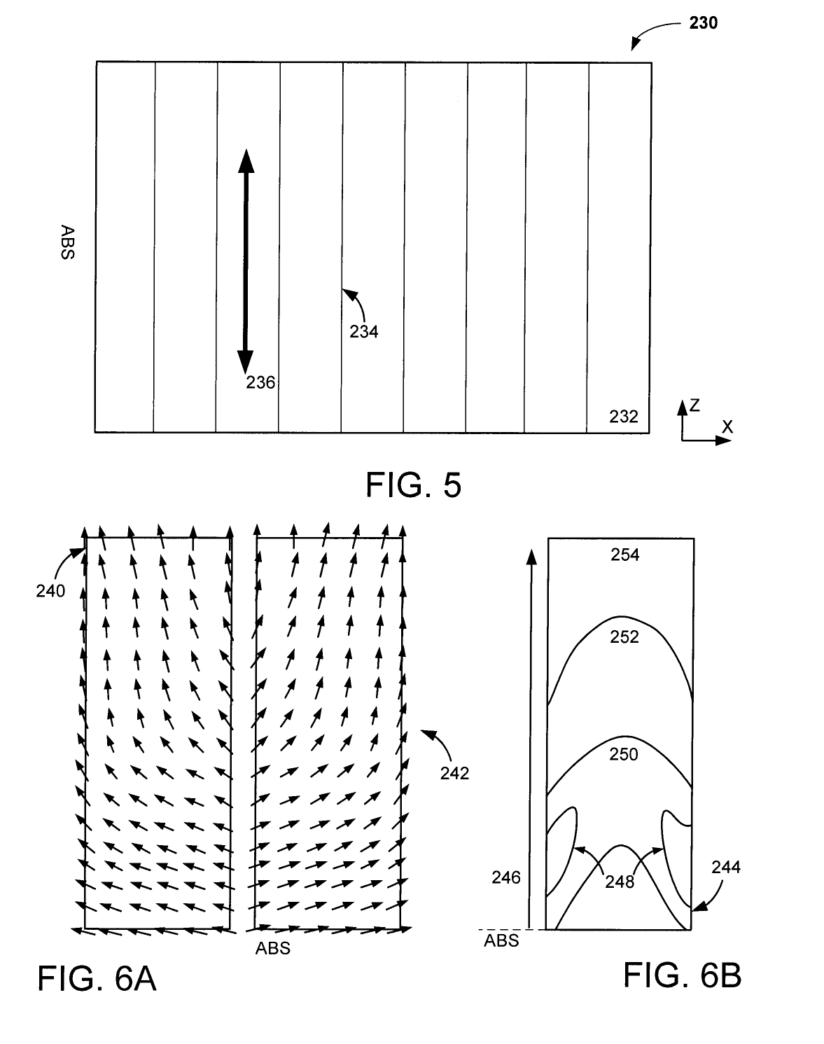

FIG. 5 shows a top view of a block representation of an example magnetic stack 230 formed with cross-track magnetization anisotropy substantially in the cross-track direction. Various unlimited formation techniques, such as oblique deposition, can be utilized to tune and optimize one or more layers 232 of the magnetic stack 230 with magnetization anisotropy along the Z axis, parallel to the ABS.

The use of substantially cross-track magnetization anisotropy is unlimited and can provide a wide variety of operational characteristics as the magnetization grains and anisotropy are tuned to designed orientations and strengths, such as approximately 1000 Oe. That is, the substantially cross-track magnetization anisotropy of a first layer of the magnetic stack 230 can be manufactured with a predetermined offset angular orientation, such as 5° from parallel with the ABS, while a second layer of the magnetic stack 230 is formed with a different predetermined offset angular orientation, such as −5° from the Z axis. Such tuning of the angular orientations of the magnetization anisotropy can allow for precise tuning of the performance of the magnetic stack 230 by optimizing the reaction to encountered data bits, which can enhance data signal amplitude.

FIGS. 6A and 6B generally illustrate operational examples of various layers 240, 242, and 244 of a magnetic stack. In FIG. 6A, micromagnetic modeling displays how a majority of each layer 240 and 242 react to encountered data bits to generate a data signal. The lack of current constriction, potentially due to the inclusion of bevel inserts as discussed in FIG. 4, allows for signal generation to be extended from the ABS, which in turn increases data signal amplitude due to the lack a majority of each layer 240 and 242 being active as opposed to acting as a shunt in a current constricted construction.

FIG. 6B further provides regions of magnetization strength that show how active proliferation of data magnetization from the ABS along the stripe height 246 of the layer 246 can correspond to enhanced data signal generation. As the layer 246 encounters a data bit across the ABS, the magnetization of the data bit can overcome the default magnetization of the layer 246 and cause the default magnetization to rotate and produce a data magnetization that has different strengths along the stripe height 246, as displayed. The ABS magnetization regions 248, proximal the ABS, can be the strongest magnetization strengths and sporadically intermixed with a second level magnetization region 250 that has a slightly lower magnetization intensity.

Moving along the stripe height 246 of the layer 244, third and fourth level magnetization regions 252 and 254 illustrate how much of the layer 244 can generate a data signal, which may correspond to more accurate data sensing due to higher signal amplitude.

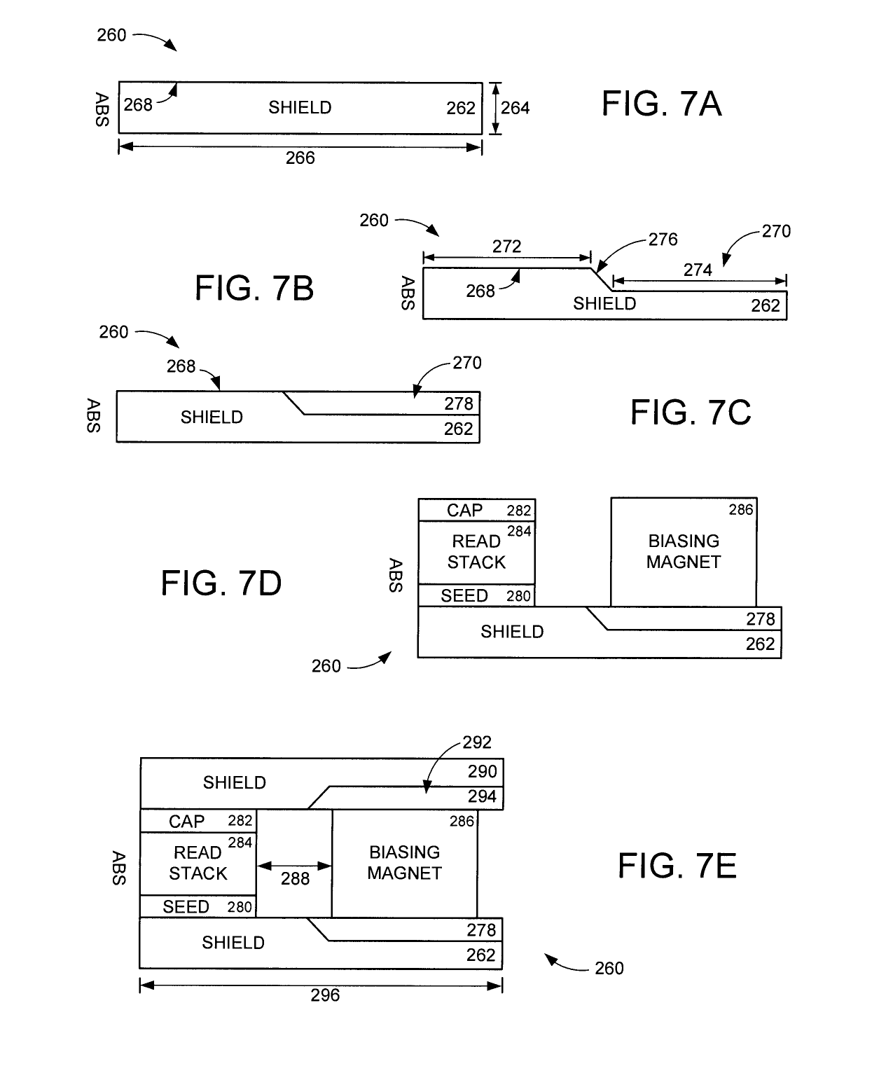

FIGS. 7A-7E generally display cross-sectional views of how the structural characteristics of an example magnetic sensor 260 can be tuned and optimized during manufacturing to provide enhanced data sensing performance. FIG. 7A shows the magnetic sensor 260 initially with a magnetic shield 262 deposited onto a substrate, such as a wafer, and having a uniform thickness 264 and a stripe height 266 that provides a level top surface 268, orthogonal to the ABS.

The magnetic shield 262 can be used with the uniform thickness 264 shown in FIG. 7A or further processed to form a beveled portion 270 that decreases the shield's thickness distal to the ABS. Processing of the magnetic shield 262 is unlimited and can be tuned with predetermined level and bevel lengths 272 and 274 connected with a transition surface 276, as shown in FIG. 7B, which can be individually shaped to provide a number of different thickness conversions.

The shaped magnetic shield 262 can then be fitted with a bevel insert 278, as displayed in FIG. 7C, that partially or wholly fills the bevel portion 270 with at least one layer that is electrically conductive and non-magnetic. The sensor 260 may then have a various decoupling layers, such as Ru seed 280 and Ta cap 282, separated by a read stack 284 comprising a lamination of magnetically responsive layers, such as a trilayer read element. The read stack 284 can correspond with a biasing magnet 286 positioned distal to the ABS, a predetermined bias distance 288 from the read stack 284, and wholly onto the bevel insert 278, as shown in FIG. 7D.

FIG. 7E further forms a second magnetic shield 290 with a bevel portion 292 that has a second bevel insert 294 coupled directly to the biasing magnet 286. While the second magnetic shield 290, bevel portion 292, and bevel insert 294 mirror the magnetic shield 262, such configuration is not limited as the shield configurations can be constructed, at will, to be unique, as displayed in FIG. 4. The direct contact of the bevel inserts 278 and 294 with the biasing magnet 286 can allow for increased read stack 284 stability and optimization of the sensor's stripe height 296 as magnetization from the biasing magnet 286 is directed to the read stack 284 instead of the magnetic shields 262 and 290.

It should be noted that the various magnetic sensor configurations of FIGS. 7A-7E are merely examples of layers, configurations, and components of a magnetic sensor and are in no way limiting or restricting. In fact, the various configurations of shield thickness, bevel portion location, bevel portion size, transition surface shape, and bevel inserts can each be uniquely tuned to provide specific performance characteristics to accommodate operational environments, such as reduced form factor and increased data transfer rate data storage devices.

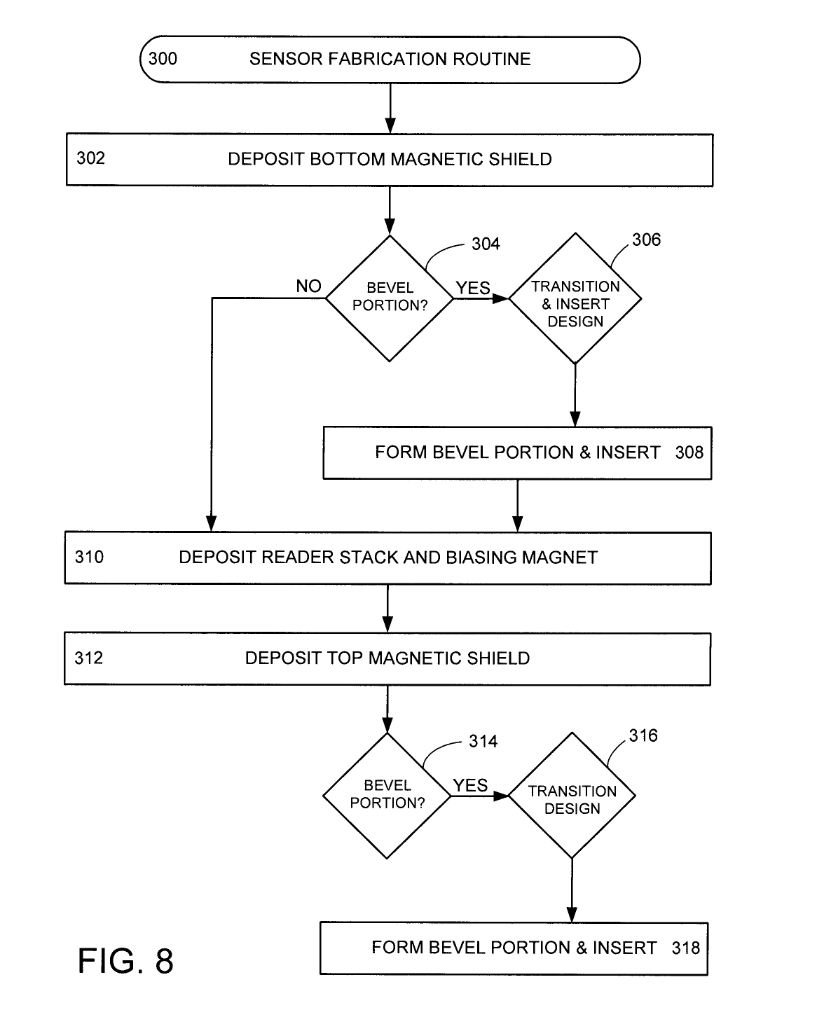

FIG. 8 provides an example flowchart of a sensor fabrication routine 300 conducted in accordance with various embodiments of the present invention. The routine 300 may begin by depositing a bottom magnetic shield having a predetermined thickness and stripe height in step 302. Decision 304 then determines if a bevel portion is to be included in the bottom shield. That is, if the bottom shield is to have a varying thickness, as shown in FIG. 7B, or a uniform thickness, as shown in FIG. 7A.

A decision to have a bevel portion advances the routine 300 to decision 306 where the design of the bevel portion, transition surface, and bevel insert is evaluated for at least size, length, and shape. The designed bevel portion is then formed into the bottom shield in step 308 with any number of unlimited material removal techniques, such as polishing and etching. Regardless of the presence of a bevel portion in the bottom shield, step 310 deposits a reader stack and biasing magnet onto the bottom shield. As discussed above, the reader stack can be deposited with techniques that provide cross-track magnetization anisotropy oriented at a predetermined angle with respect to the ABS of the read stack.

The reader stack and biasing magnet can each be tuned at least by positing the components in relation to the bevel insert and transition surface to provide predetermined operational behavior for the read stack. Next, a top magnetic shield can be deposited, in step 312, onto the existing read stack and biasing magnet. Decisions 314 and 316 subsequently determine if and how a bevel portion is to be formed into the top shield in a manner similar to decisions 304 and 306. In the event a bevel portion is not chosen, the routine 300 can terminate or proceed to additional steps not shown in FIG. 8. If a bevel portion is chosen in decision 314, the designed bevel inserts and bevel portion will be formed into the top shield in step 318.

It can be appreciated that a wide variety of magnetic sensors can be constructed from the routine 300 that exhibit various structural and operational characteristics, such as greater signal generation and magnetic stability due to cross-track magnetization anisotropy and magnetically non-conductive bevel inserts. The routine 300, however, is not limited only to the steps and decisions provided in FIG. 8 as any number of steps and determinations can be added, omitted, and modified to accommodate the fabrication of a precisely tuned magnetic sensor with enhanced magnetic shielding and data sensing.

Further of note is that no particular deposition and formation processes are required to deposit the various layers in the routine 300. For example, atomic layer deposition can be used for some layers while vapor layer deposition can be utilized for other layers. Such an ability to use various formation processes can allow further ability to tune magnetic sensor fabrication with improved manufacturing efficiency and reliability.

It can be appreciated that the configuration and material characteristics of the magnetic sensor described in the present disclosure allows for enhanced data reading performance while allowing for reduced form factor applications. The use of varying shield thicknesses and bevel inserts may provide increased magnetic stability through isolation of the biasing magnet from the magnetic shields. Moreover, the utilization of substantially cross-track magnetization anisotropy in the read stack allows for the utilization of a majority of the read stack's stripe height for signal generation as current constriction is prevented from increasing electrical resistance and noise during operation. In addition, while the embodiments have been directed to magnetic sensing, it will be appreciated that the claimed invention can readily be utilized in any number of other applications, including data storage device applications.

It is to be understood that even though numerous characteristics and configurations of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed. For example, the particular elements may vary depending on the particular application without departing from the spirit and scope of the present invention.

What is claimed is:

1. An apparatus comprising a magnetically responsive stack positioned on an air bearing surface (ABS) and disposed between first and second magnetic shields each with a beveled portion distal to the ABS, the magnetically responsive stack having a cross-track magnetization anisotropy proximal to the ABS.

2. The apparatus of claim 1, wherein each magnetic shield has a level portion proximal to the ABS and adjacent the beveled portion.

3. The apparatus of claim 1, wherein each beveled portion is adjacent a bevel insert constructed of electrically conductive, non-magnetic material.

4. The apparatus of claim 3, wherein at least one beveled portion is adjacent a conductive, non-magnetic lamination.

5. The apparatus of claim 1, wherein the magnetically responsive stack is a trilayer element with a plurality of magnetically free layers separated by a non-magnetic spacer layer.

6. The apparatus of claim 5, wherein a permanent biasing magnet is positioned substantially between the first and second shields proximal to the beveled portions and distal to the ABS.

7. The apparatus of claim 1, wherein the cross-track magnetization anisotropy is substantially parallel to the ABS.

8. The apparatus of claim 1, wherein the cross-track magnetization anisotropy has a predetermined angle in relation to the ABS.

9. The apparatus of claim 1, wherein the cross-track magnetization anisotropy is approximately 1000 Oe.

10. The apparatus of claim 1, wherein at least one beveled portion is contactingly adjacent a bevel insert constructed of metallic material.

11. A method comprising creating a cross-track magnetization anisotropy in a magnetically responsive stack proximal to an air bearing surface (ABS), the magnetically responsive stack between first and second magnetic shields on the ABS, each magnetic shield with a beveled portion distal to the ABS.

12. The method of claim 11, wherein at least one beveled portion is contactingly adjacent a bevel insert formed of conductive, non-magnetic material that stabilizes the magnetically responsive stack.

13. The method of claim 11, wherein the cross-track magnetization anisotropy extends a signal generation region of the magnetically responsive stack distal to the ABS.

14. The method of claim 12, wherein the cross-track magnetization anisotropy is created by static oblique deposition at a first predetermined angle.

15. A sensor comprising:
a magnetically responsive stack positioned on an air bearing surface (ABS) and disposed between first and second magnetic shields each with a beveled portion distal to the ABS, the magnetically responsive stack having first and second ferromagnetic free layers separated by a non-magnetic spacer layer, the first and second ferromagnetic free layers respectively configured with first and second cross-track magnetization anisotropies proximal to the ABS.

16. The sensor of claim 15, wherein the first cross-track magnetization anisotropy is different from the second cross-track magnetization anisotropy.

17. The sensor of claim 16, wherein the first cross-track magnetization is created by oblique deposition of a first predetermined angle.

18. The sensor of claim 17, wherein the second cross-track magnetization is created by oblique deposition of a second predetermined angle, the first and second predetermined angles being different.

19. The sensor of claim 15, wherein a rear biasing magnet is positioned between the beveled portions of the magnetic shields.

20. The sensor of claim 15, wherein at least one beveled portion is filled with a bevel insert formed of non-magnetic, electrically conductive material.
